(19) United States
(12) Patent Application Publication
(10) Pub. No.: US 2011/0017273 A1
(43) Pub. Date: Jan. 27, 2011

(54) Concentrated Solar Heating

(75) Inventors: Robert Roach, Ramat Hasharon (IL); Eliezer Abraham Schwartz, Herzliya (IL); Nir Giora, Herzliya (IL)

Correspondence Address: The Law Office of Michael E. Kondoudis, 888 16th Street, N.W., Suite 800, Washington, DC, 20006, US

(73) Assignee: SAHAR G.N. INTERNATIONAL LTD., Herzliya (IL)

(21) Appl. No.: 12/921,255

(22) PCT Filed: Mar. 12, 2009
(86) PCT No.: PCT/IL2009/000283

§ 371 Date: Sep. 7, 2010

Related U.S. Application Data
(60) Provisional application No. 61/036,086, filed on Mar. 13, 2008.

(51) Int. Cl. H01L 31/052; F24J 2/38; F24J 2/12; F24J 2/24

(52) U.S. Cl. 136/246; 126/600; 126/694; 126/651

(57) ABSTRACT

A system for concentrating solar energy comprising a collector consisting of a number of reflective panels, a receiver which absorbs reflected energy, a working fluid which absorbs the energy, a highly transmissive cover and internal colorings or coatings to collect indirect radiation, and a solar tracking system to maintain reflector orientation. Optional photo-voltaic panels could also be used for providing electrical energy and are kept at near ambient temperatures. Under normal conditions, solar energy is concentrated by reflectors on the receiver, which transfers the energy to a working fluid which is then used for either hot water heating, desiccant drying for a solar air conditioner, or as a power source. Additional energy is collected from indirect sources using the greenhouse effect.

### FIELD OF THE INVENTION

The present invention generally relates to systems in which solar energy is concentrated for purposes of generating heat or power.

The present invention particularly relates to a system for providing residential hot water by concentrating solar energy.

The present invention particularly also relates to a system for providing concentrated solar energy to act as an energy source for drying desiccants in a solar air conditioning system.

The present invention particularly also relates to a system for providing concentrated solar energy as a source of heat for devices as absorption chillers which provide any of heated or cooled water and heated or cooled air.

The present invention particularly also relates to a system for providing concentrated solar energy as a source of heat made available through heat exchangers for power generation.

### BACKGROUND OF THE INVENTION

Efficient use of solar energy has been a goal for as long as using solar energy has been around; agriculture being a prime example where direct and diffused solar energy is used by plants. Concentrated solar energy has been around over a much shorter interval. It is the goal of this disclosure to present a highly efficient solar collector which is scalable from residential use to larger commercial enterprises and can be used with this same high efficiency for virtually any of several purposes for which solar energy will provide power. These purposes are primarily residential or small business hot water heating, power generation, air conditioning, and space heating.

It is a further goal of this disclosure to provide a system which is inexpensive both in construction and in the choice of materials. No currently existing solar collector can provide the consistently high efficiency of the disclosed system across such a spectrum and maintain a low cost. But by combining several existing concepts, however, such a system can be devised.

Efficiency is defined in several ways, but for purposes of this disclosure, solar power efficiency will be defined as the fraction of solar power utilized from that directly available per unit area. It is likewise desirable for the solar collector to occupy the smallest space possible so that roof tops of apartment buildings, for example, may be able to sustain a large number of collectors for all the apartments.

Not included in the efficiency calculation is the extra solar radiation available indirectly. This energy comes from that scattered by the atmosphere and that reflected off of nearby surfaces such as buildings, walls, bodies of water, and so forth. This energy normally amounts to another 20-30% of the energy available directly from the sun. It is a goal of the present system to be able to absorb some of this energy as well.

What is needed is a system which will collect a high fraction of the direct and indirect solar energy incident on the area occupied by the collector and use it to either generate electricity or heat a working fluid or both. When heating a working fluid, it is desirable to heat this fluid as rapidly as possible to the desired temperature. Systems which may make use of such a heated fluid include but are not limited to hot water system, desiccant-based solar air conditioners, absorption chillers, and power generation systems. Absorption chillers and small scale power generation units work best when the temperature is near or above the boiling point of water and large scale power generation systems work best when the temperatures are significantly higher.

### Existing Systems

Current systems include flat plate solar panels, common in solar water heating, evacuated tube solar collectors, also used for hot water and other uses, and parabolic trough collectors. Less common are circular parabolic collectors. The parabolic collectors are examples of concentrating designs as are the large scale systems where a large number of flat mirrors reflect solar energy to a tower for purposes of generating steam for power generation. Each of these systems has limitations.

Flat panel solar collectors, such as those used in domestic hot water heating, make use of greenhouse effect to heat up an enclosed box with a transparent cover exposed to the sun. Both direct and indirect energy are collected. Limitations of these flat panel collectors include the fact that these panels are typically stationary and at hours of the day where the sun is not directly overhead are receiving only a fraction of the energy they could receive because of the oblique angle of the sun with respect to the panel normal. That is, the flat panels do not follow the sun to get the full exposure possible. Generally this represents a loss of up to 20-30% on a typical day. Overall, flat panel efficiencies typically vary from 40-60%. It is possible for a flat panel system to be designed to follow the sun, but the cost would more than double. It would be simpler to provide reflectors around the flat panel which moved with the sun to make up for the loss.

Flat panel collectors typically heat the working fluid to around 70-80° C. which is low for absorption chillers which are redesigned for the lower temperatures but do not work as efficiently as they could. There are specially designed flat panel collectors whose working temperatures are higher and these are better for this purpose, but the panel cost is nearly doubled.

Flat panel collectors are mostly used for residential solar hot water heating. They are also used with some absorption chillers but with the reduced efficiency of the lower temperature. There are also some flat plate designs in which photovoltaic panels are placed inside the collector so that both electricity and working fluid heating are provided. There are difficulties in maintaining efficiency of such systems due to the drop in PV efficiency with temperature and the working fluid heating acts as a kind of radiator for the PV panels. However, once the water in the tank has reached its temperature, some means must be provided to continue to cool the PV panels which requires additional controls.

Much has been written of the efficiency of the evacuated tube collectors which are quite efficient if one calculates the efficiency using only the area that the tubes occupy. But these systems require spacing between the tubes to avoid shadowing each other. Incident energy between the tubes is thus lost. The situation is worse when one realizes that the solar energy reflects off the surface rather being absorbed when the angle between the incident energy and the surface normal exceeds, say 60°. Hence only about 75% of the cross-sectional area of the tube is effective at energy absorption. Some of this reflected energy is picked up by the neighbor tubes but it does not make up for that lost by reflection. Thus the overall efficiency of the evacuated tube collector per area occupied is lower than that of the flat panel collector. The round tubes do allow for collecting the same fraction of solar energy throughout most of the day until the sun is low enough that the tubes begin to shadow one another, and the evacuated tube collector does allow a much higher temperature of the working fluid. As a consequence, these are better for absorption chillers at the cost of having a higher collector footprint. Evacuated tubes are mostly used for solar hot water heating but there are some absorption chillers which make use of the heated working fluid to work. These should work well except for the large area taken by the evacuated tube array.

Parabolic trough collectors concentrate solar energy to a receiver tube oriented at the focal point of the parabola. So far these systems have been used only for large energy producing facilities and use rather high concentration ratios in order to raise the temperatures to several hundred degrees. At such high temperatures, there are losses due to conduction, convection, and radiation. Surrounding the receiver with a glass tube virtually eliminates convection losses leaving losses only due to conduction and radiation with the latter being the largest at the higher temperatures. Since the losses are proportional to the exposed area, the receiver tubes are made small. As a consequence, the tracking accuracy must be quite high and, since the structures are large for the power required, must also have a structure which can withstand distortions due to wind loading. Both the tracking and structure contribute greatly to a higher cost. Apart from these, another factor reducing the overall efficiency of the parabolic trough collector is the inability to absorb indirect radiation unlike the flat panel and evacuated tube collectors.

Circular parabolic reflectors and those using Fresnel lenses to focus on solar photovoltaic cells are another example of concentrating systems. These suffer the same disadvantages as the parabolic trough collectors. In addition, the Fresnel lens concentrating systems have reduced efficiency due to the passage of the energy through the lens. The Fresnel lenses are typically made of polymethyl methacrylate which is a low weight and low cost alternative to glass with a relatively high transmissivity of 92% meaning 8% of the energy is lost immediately. While this can be improved by a few percent with anti-reflective coatings (see for example, AR4001 coating by Reflexite Display Optics). Solar tracking is also required for these systems with a very large drop in efficiency with any tracking errors though this could be designed around at the expense of some efficiency.

There is therefore a need to provide a general purpose, low cost solar collector which maintains high efficiency across a spectrum of needs and which can gain additional performance by being able to collect indirect radiation. There is further need to provide an efficient means of concentrating solar energy onto photo-voltaic cells without sacrificing efficiency by maintaining a low PV temperature.

### Representative Solar Water Heater Patents

Reference is made to U.S. Pat. No. 4,979,493 (Seidel—25 Dec. 1990) included here by reference wherein the general layout of efficient solar water heating making use of flat panels is described. In this patent a number of existing piping methods are described and innovative alternatives are proposed to overcome certain difficulties with night-time cool-down, cold weather freezing, and the like.

### Representative Paneled Parabolic Solar Collectors

Reference is made to U.S. Pat. No. 4,011,858 (Hurkett—Mar. 15, 1977) included here by reference wherein a cylindrical parabolic reflector concentrates the sun's energy on a pipe at the parabolic focus. The parabolic reflector can rotate to follow the sun and thus maintain the focus of energy on its axis for all daylight hours. The receiving pipe is also along the axis of rotation simplifying the connection with the rest of the system as it does not need to rotate with the parabolic reflector. Although this was not specifically mentioned in the text, it is clear from the drawings that this is what was meant for the mechanical arrangement. Further, this patent discloses that this device is only intended for heating water.

Reference is made to U.S. Pat. No. 4,106,480 (Lyon, Harrison—Aug. 15, 1978) wherein a series of essentially parabolic panels are individually rotated to follow the sun. Arguments are presented justifying the parabolic shape on an essentially extended receiving surface because of diffusion. The panels are rotated individually in order to fit the entire device between roof joists out of an aesthetic desire and also to simply shielding the device from wind and other environmental elements. Such an arrangement will necessarily ultimately leave shadows from the edges of one reflector on another at the early and late hours of sunlight thereby reducing the collection efficiency. Since the present system does not anticipate being placed between roof joists, many of the restrictions imposed on system described in U.S. Pat. No. 4,106,480 lead to more a more efficient design. Their argument for shielding the system between roof joists because of protection from elements is really only true in extreme environments. Their essentially parabolic arc reflectors will not cover the entirety of the cylindrical receiver, meaning that the solar radiation is of higher temperature along a strip thereby increasing the heat loss by radiation.

Another arrangement using a parabolic reflector is disclosed in U.S. Pat. No. 4,038,972 (Orrison—1977) included here by reference in which a genuinely parabolic trough reflector concentrates the sun's rays toward a secondary mirror which finally focuses the rays to a receiving pipe in a smaller trough near the center of the parabolic reflector. The parabolic reflector is rotated to maintain alignment of the sun's rays and the secondary mirror. A significant disadvantage of this arrangement is that the receiving pipe moves with the reflector and hence fittings and connections with the rest of the system must be flexible to allow for this movement. Use of a secondary mirror also results in a small efficiency loss.

Another means of trying to optimize the amount of heat added to a receiver is given in the solar parabolic reflector of U.S. Pat. No. 4,026,273 (Parker—1977), included here by reference. A series of fins are used to supposedly add extra concentrating of solar energy to the receiver. A primary concern in this patent is to make up for imperfections in the parabolic mirror which might result in off axis spreading of the concentrated solar energy.

To avoid the expense and complexity of following the sun, another reference U.S. Pat. No. 3,964,464 (Hockman—Jun. 22, 1976) used several parabolic reflectors stacked on top of one another so that as the sun moves, the reflection from the top surface of an outer reflector will strike the rear face of the next inner reflector. The rear faces are as polished as the sun-side faces and hence reflect the energy back to the outer reflector but further toward the focus. After a few more reflections, the energy is presumed to finally hit the receiving pipe which is a helical coil of black-painted copper tubing. If the arrangement is successful in transferring all incident radiation over the surface of the collector, the maximum energy received through the day is still only 64% of what would have been received had the device been able to follow the sun and keep the full face toward it. The helical receiver coil is claimed to have 7 times the area of a conventional straight pipe which it does, but this does not change the either the amount of energy which can be absorbed nor the flow rate of the fluid thus heated. The authors misunderstand heat transfer and flows. Hence, the advantage of the coil to enlarge the area of absorption so that flat panels can be used is not obvious. In fact, the larger exposed area more likely results in higher heat loss since the losses are proportional to the exposed area. Further, the multiple reflections also result in small efficiency losses with each reflection.

Reference is made to U.S. Pat. No. 6,336,452 B1 (Tirey, Jr.—8 Jan. 2002) herein included by reference describing a parabolic reflector which is circular (like a radar dish) in its dimension exposed to the sun rather than rectangular (trough-like). Near the focal point, a second reflective surface deflects the energy to a coiled tubing in which a working fluid is heated. No attempt is made to explain the coiled tubing further other than to provide a picture. No other embodiments of that arrangement are claimed.

Examples of Concentration using Fresnel Lenses

Reference is made to U.S. Pat. No. 4,280,853 (Palazzetti et. al.—1981) herein included by reference which describes the use of Fresnel lenses concentrating solar energy onto individual solar photovoltaic cells. Cooling of the heated cells is anticipated using a liquid coolant, though the heat is dissipated without use and provision for solar tracking is indicated.

Reference is made to U.S. Pat. No. 4,848,319 (Appeldorn—1989) herein included by reference which describes using Fresnel lenses for concentrating solar energy onto a photovoltaic cell. The idea is to provide a light-weight structure and to reduce the cost of the apparatus by using concentration. In this effort, the Fresnel lens is folded in an attempt to provide good collection as the sun moves through the sky. The efficiency of such a system is necessarily lower than that of a system which uses solar tracking and a single flat Fresnel lens.

Reference is made to US Patent 2008/0314436 A1 (O'Connell et. al—2008) wherein one or more Fresnel lenses direct a wider range of frequencies of incident solar radiation onto the photo-voltaic cells in order to improve efficiency.

No concentrating system known to the inventors anticipates additionally trying to capture indirect radiation as well as direct.

### Application to Solar Air Conditioning

Reference is made to U.S. Pat. No. 6,513,339 (Kopko—2003) herein included by reference which describes the first low-cost, practical solar air conditioner which makes use of desiccants for efficient energy storage and from which water is evaporated. The system described indicates that a solar collector of some sort would be used to dry the desiccant but discloses no details of such a collector other than how it would be protected from the elements. The required temperature for efficient water evaporation of the desiccant solution is around 100° C. Such a high temperature is not reached by a common flat solar panel used in the usual solar water heaters wherein water is heated by greenhouse effect in a blackened box. The proposed system here is ideal for providing such temperatures. Further, the efficient concentration of solar energy and sun tracking significantly extend the length of time that solar energy could be used to evaporate water from the desiccant solution and further minimizing use of the auxiliary electrical heating required in periods of low sun and at night.

### Solar Tracking

There are a variety of methods known in the art to cause a system to position itself relative to the position of the sun. Two well-known methods use differential radiation and clock timing. The first is based on equal lighting of two sensors when the system is aligned and the other is based on the fact that since the sun's position and the time of day are related directly, a clock motor or a device based on a clock drive will compensate for the earth's rotation and hence the sun's position.

Reference is made to U.S. Pat. No. 4,821,705 (Trihey—Apr. 18, 1989) solar tracker device based on relative solar radiation on two solar cells. When the two cells receive the same energy the system is aligned with the sun. When the system is not aligned, one cell will receive more energy than the other which causes a motor to rotate the system about the axis until it is re-aligned.

Reference is made to U.S. Pat. No. 4,794,909 (Eiden—Jan. 3, 1989) solar tracker device based on clock signals to continuously activate and deactivate a motor which drives the collector to be aligned with the sun. The system includes an over-ride which moves the system out of solar alignment if the temperature exceeds a maximum value.

### SUMMARY OF THE INVENTION

It is the object of the present invention to disclose a system for concentrating solar radiation for the purpose of providing heat and power. It is another object of the present invention to show that a very high fraction of the incident radiation arrives at the collector, unlike previous methods of concentration which use secondary reflectors or multiple reflections.

It is an object of the present invention to disclose the avoidance of energy loss due to reflections from a low incidence angle of the energy on the receiver. One unappreciated problem of concentrating solar energy is the reflection of incoming energy off of the receiver element. Generally, the receiver element is round as in tubing or piping (defined below) and the incoming energy is incident to the normal of the tube axis. As such, it encounters a range of incidence angles with respect to the receiver surface. When the incidence angle is low enough, the surface acts as a reflector rather than an absorber and the incident radiation is lost. These same phenomena cause mirages. On the other hand, if the energy is concentrated in too small an area on the receiver, it will heat up giving a large temperature and large temperature gradient, which then loses heat by radiation, convection, and conduction to the surroundings. Hence, it is advantageous for the collector to spread the radiation over only a portion of the receiver surface without over-concentrating it in one spot. A strictly parabolic reflector, whose focus is along the axis of a receiver, will be an ideal candidate since every segment of the reflector will place its energy on a different spot of the receiver and whose incidence is normal. However, great construction and cost advantage can be attained if one uses a series of narrow flat panel reflectors, also along a parabolic arc, which reflect energy to a portion of the receiver surface. Hence, this invention encompasses all flat panel reflecting surfaces which have panel widths to reflect solar energy over some maximum portion of the receive diameter down to a zero width, which then becomes a strictly parabolic reflector. All such reflectors are thus advantageous for avoiding the losses associated with reflection and over-concentration.

A significant advantage of the flat panel construction is that it is much easier to manufacture than the parabolic reflector. One disadvantage is that, with the change in angles, the panels are of different widths so that they must be individually made if one wishes to keep the same fraction of exposure to the receiver. If this requirement is relaxed, then all the reflectors can be made the same width.

Another object of the present invention is to disclose the efficiency gains possible by using a receiver with multiple layers. Multiple layers within the receiver allow excess heat in one layer to be absorbed by a cooler neighbor layer. This reduces losses to surroundings. Although losses to the surroundings can also be reduced by placing the receiver in an enclosed, but transparent casing (preferably at reduced pressure), as is known in the art, multiple layers allow for quicker transfer of energy to the working fluid reducing the losses if one chooses not to have such an enclosure.

It is another object of the present invention to disclose the advantage of having the working fluid within the receiver to flow in opposite directions in the different layers. This allows a more uniform distribution of temperature over the length of the receiver, thereby reducing the tendency for the receiver to have a generally hot end and cold end. Of course, there will be a cold fluid entrance and a hot fluid exit, but these may now be placed at the same end which simplifies the design.

Another object of the present invention is to disclose a solar concentration system which tracks the sun's position so that this maximum heat may be maintained for the most part of daylight hours. Most existing solar hot water systems use one or more large flat panels which are stationary. Even if they are oriented at the optimum angle for a day, at only one instant during the day is the sun directly overhead. Thus, during the rest of the day, the effective collection area is reduced. Overall, such systems are capable of receiving, at most, around 64% of the available energy. By following the sun, this increases to nearly 100%. Such a concept is known in the art and it is used here. It is also known in the art to rotate the system about the focal point of a parabolic reflector. Such is the case here where the axis of rotation is along the axis of the receiver. Here, we rotate only the reflector system and leave the receiver stationary. This simplifies the design. It is also possible to rotate the receiver with the reflector.

Another object of the present invention is to disclose a system, wherein the collector makes use not only of concentrated solar energy but also of greenhouse effect heating by absorbing indirect solar energy. Such greenhouse heating is made possible by encasing the receiver in a transparent enclosure, or, better, encasing the entire system in a transparent enclosure. Greenhouse effect heating adds another component to the energy absorption by trapping radiation from that scattered by the atmosphere and any other surrounding reflective surfaces such a bodies of water, nearby glass buildings, etc. A second advantage of the transparent enclosure and another object of the present invention is to disclose a system that minimizes the convective losses by housing the receiver in a highly transparent covering. Although, this is not a requirement, a fully optimized system would include such an enclosure to minimize losses to the surroundings as the system heats up.

Another object of the present invention is to disclose use of photovoltaic (PV) cells at the receiver to generate electrical power. The cells located thus will be receiving concentrated energy from the collector and hence generate more power than a simple direct exposure to the sun. Virtually any PV cell will work in the present invention whether high temperature or otherwise, because the waste heat which would ordinarily raise the working temperature of the cells, which work at reduced efficiencies at higher temperatures, is carried away by the working fluid within the receiver. Use of concentration on the PV cells reduces the number of required cells and hence considerably lowers the system cost for electrical power generation.

### BRIEF DESCRIPTION OF THE DRAWINGS

In order to understand the invention and to see how it may be implemented in practice, a plurality of preferred embodiments will now be described, by way of non-limiting example only, with reference to the accompanying drawing, in which

FIG. 1 illustrates a non-dimensionally scaled cross-sectional view of the concentrated solar heating system according to an embodiment of the present invention;

FIG. 2 illustrates a non-dimensionally scaled cross-sectional view of the collector subsystem according to an embodiment of the present invention;

FIG. 3 illustrates a non-dimensionally scaled cross-sectional view of the receiver subsystem according to an embodiment of the present invention;

FIG. 4 illustrates a non-dimensionally scaled cross-sectional view of a typical solar hot water system according to an embodiment of the present invention;

FIG. 5 illustrates a non-dimensionally scaled cross-sectional view of a possible solar air conditioning system according to an embodiment of the present invention;

FIG. 6 illustrates a non-dimensionally scaled cross-sectional view of the collector subsystem according to an embodiment of the present invention which includes Photo-Voltaic panels;

FIG. 7 illustrates a non-dimensionally scaled solar application involving an absorption chiller

FIG. 8 illustrates a typical solar power application according to an embodiment of the present invention;

### DESCRIPTION OF THE PREFERRED EMBODIMENTS

The following description is provided, alongside all chapters of the present invention, so as to enable any person skilled in the art to make use of said invention and sets forth the best modes contemplated by the inventor of carrying out this invention. Various modifications, however, will remain apparent to those skilled in the art.

In the following detailed description, numerous specific details are set forth in order to provide a thorough understanding of embodiments of the present invention. However, those skilled in the art will understand that such embodiments may be practiced without these specific details. Reference throughout this specification to “one embodiment” or “an embodiment” means that a particular feature, structure, or characteristic described in connection with the embodiment is included in at least one embodiment of the invention. Thus, the appearances of the phrases “in one embodiment” or “in an embodiment” in various places throughout this specification are not necessarily all referring to the same embodiment or invention. Furthermore, the particular features, structures, or characteristics may be combined in any suitable manner in one or more embodiments.

The drawings set forth the preferred embodiments of the present invention. The embodiments of the invention disclosed herein are the best modes contemplated by the inventors for carrying out their invention in a commercial environment, although it should be understood that various modifications can be accomplished within the parameters of the present invention.

The terms ‘tubing’ or ‘piping’ relates hereinafter in a non-limiting manner to any conduit through which a liquid or gas can flow without referring to the type of material (though if high heat is involved we generally mean metal or some other heat-capable material) and, as is common in the art, a pipe generally refers to a nonflexible conduit and a tube means flexible.

The term ‘collector’ relates hereinafter in a non-limiting manner to the generally parabolic shaped reflecting surface which incident solar radiation first impacts.

The term ‘receiver’ relates hereinafter in a non-limiting manner to the surface which receives the incident solar energy from the collector. The receiver is also responsible for transferring the received energy to the working fluid flowing within.

The term ‘working fluid’ refers to any liquid or gas which absorbs the energy received by the receiver. If the fluid is a liquid, it may be advantageous for it to be converted to its gas phase with an attendant expansion which may be useful for driving a piston. Such is common in solar powered steam generators. The working fluid could be water as in the case of some residential solar hot water systems. In colder climates when exposed pipes can freeze if they contain water, it is more typical to use an antifreeze for the working fluid.

The term ‘solar-tracking’ will be used interchangeably with ‘sun-following’ and will be considered identical and will mean any method or mechanism whose aim to keep a constant angle with respect to the position of the sun. Specifically, here, it will mean keeping the angle of the short dimension of the reflecting surfaces at a constant angle to the sun.

The system is designed to receive incident solar energy, concentrate it on a receiver surface and then use the concentrated energy to heat a working fluid which is then used for a number of possible applications.

The term ‘greenhouse effect’ will refer to solar radiation which is indirect rather than directly from the sun. Such radiation comes from that reflected from nearby objects such as bodies of water, buildings, the sky, and so forth.

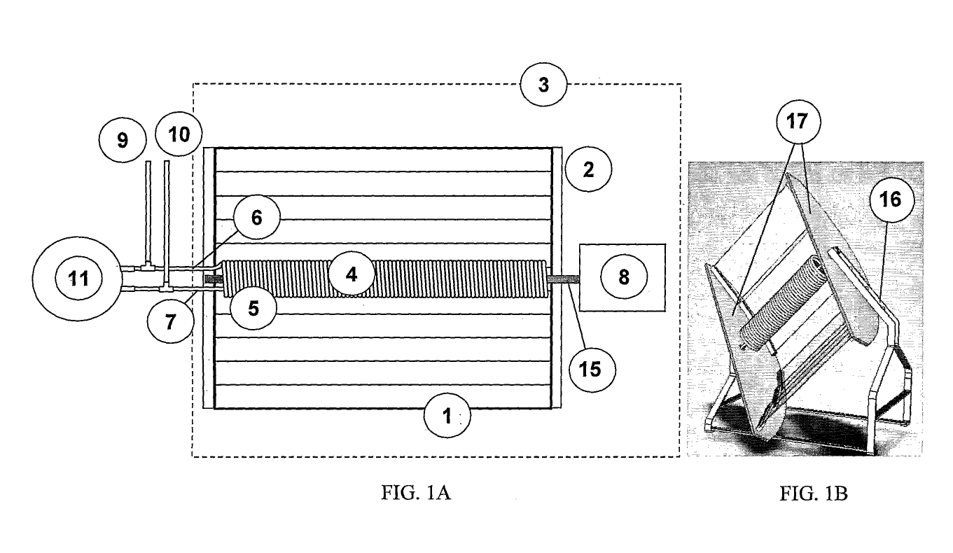

Reference is now made to FIG. 1a, which is a cross-sectional view of a system for concentrating solar energy in order to attain high heat transfer rates and temperatures. A set of reflecting surfaces 1 are arranged on a frame 2 in such a way as to focus incident solar energy onto a receiver 4. The receiver 4 consists of a first receiving surface 5, which allows the energy to be transferred to a working fluid 6 within the said first surface. Thus the first surface represents an enclosure to contain the working fluid. The working fluid may consist of any suitable liquid or gas depending on the application of solar concentrating system. For example, if the application is a home hot water heating system as shown in the figure, then the working fluid may be water. In cooler climates, the working fluid may be a substance which does not freeze at typical winter temperatures such as ethylene glycol. In such cases, a second heat exchanger, not exposed to the outside elements, is then used to heat the water. Such systems are in common use in Europe. The Receiver 4 may also consist of a second enclosure 7 internal to the first enclosure and connected to it in such a way as to allow excess heat to be transferred to the inner enclosure. The working fluid in the inner enclosure 7 first passes through the inner enclosure before passing through the said first enclosure 5. One purpose for such an arrangement is to preheat the working fluid within the inner enclosure with excess or radiated heat from the said first enclosure. The radiated heat might otherwise be lost.

The reflecting surfaces maintain orientation toward the sun by the sun-following mechanism 8. Sun following is well known in the art and many such systems exist based on clock drives, solar angle sensors, and so forth.

The working fluid may have an inlet 9 where new fluid enters the system, such as water in a hot water system as shown. The working fluid may also have an outlet 10 where the fluid exits the system for use such as in a hot water system as shown. There are a large number of possible ways in which the Receiver could be connected to the rest of the system 11 depending on they type of system The drawing does not necessarily reflect a useful one, but the manner in which the connections are made will be obvious to anyone skilled in the art.

Reference is made to FIG. 1b, which shows a possible embodiment of a frame 16 which holds the collector and ends of the collector 17. The internal surfaces of the ends may be painted or otherwise made a dark color to assist with the absorption of indirect radiation.

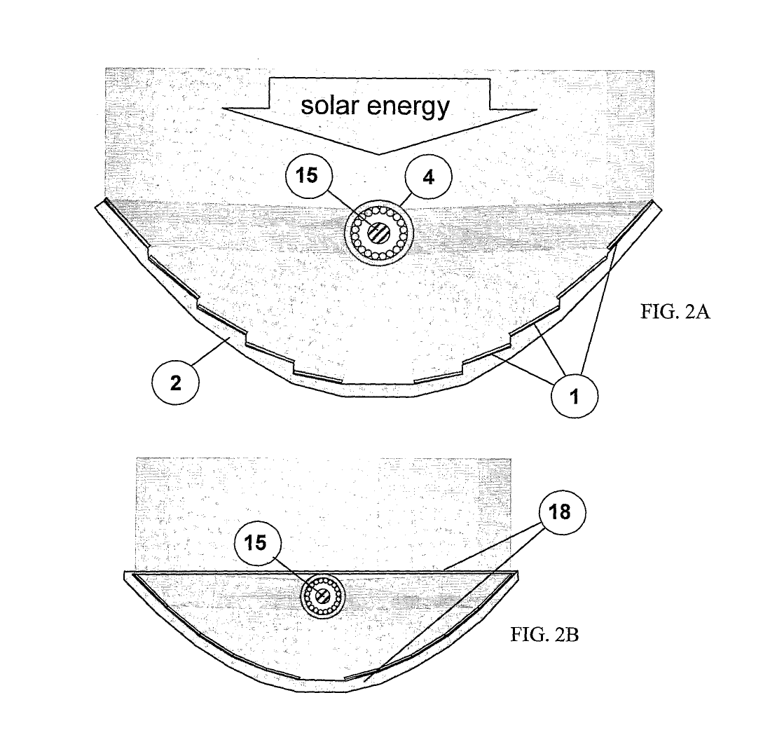

Reference is now made to FIG. 2a which is a cross sectional view of a fundamental configuration of the reflecting surfaces in the disclosed invention. Solar radiation is incident on the surfaces 1 whose orientation with respect to the sun always allows the incident energy to be reflected to the receiver. The center of the reflected beam will strike the corresponding center of the receiver 4. The width of the reflected energy is less than the width of the receiver to avoid losing energy due to reflection from the receiver. The panels are also placed in such a way that no panel casts a shadow on another. The panels may be spaced accordingly as in the figure to allow for air to pass through of the optional enclosure is not used. Allowing the air to pass through the panels reduces the aerodynamic load on the structure when there are winds. When the optional enclosure is not used, there is no need for this spacing.

Reference is now made to FIG. 2b which is a similar cross sectional view to that in FIG. 2a in which there is no gap between the panels and represents an embodiment with a complete enclosure so that the greenhouse effect may also be used for greater heating. A second advantage of a complete enclosure is the reduction in aerodynamic forces during winds so that the support structure need not be as strong as the open configuration in FIG. 2a. A third advantage of the enclosure is the protection offered the reflective surfaces from falling debris or other environmental hazards.

The positions of the panels shown in FIG. 2a and FIG. 2b are for illustrative purposes only and only show one geometrical embodiment. The number of panels may vary from 1 to as many as desired and can be designed to either reduce the width of the reflected energy or to fit within a certain enclosure size. It should be obvious, though, that more energy will be collected from a larger total projected (toward the sun) area. The figure illustrates a scaled system for a residential hot water heater.

The reflecting surfaces may be made of any material suitable for reflecting the majority of the incident solar radiation, but preferably made of a highly reflective material. Such materials include front surface mirrored glass, polished aluminum, and other surfaces known in the art for reflecting solar energy.

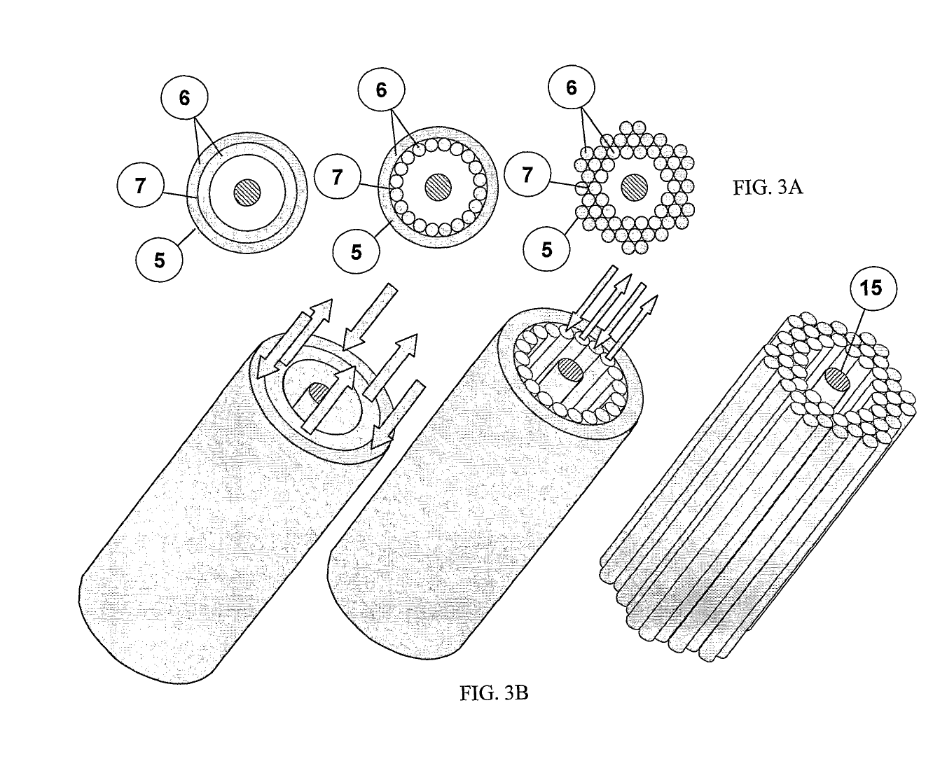

Reference is now made to FIG. 3 which shows cross-section views of three fundamental configurations of the receiver 4. The receiver is made of an inner enclosure 7 and an outer enclosure 5 through which the working fluid 6 passes and absorbs the solar energy by conduction. The receiver itself absorbs energy incident on it also by conduction. It should be appreciated that the figure shows only three embodiments and that virtually any type of inner or outer enclosures may be used, including but not limited to annular inner and outer enclosures, enclosures made of tubing of any cross section shape (but usually circular), inner and outer enclosures which are made of coiled tubing, or any combination.

The enclosures are open in the middle to allow space for the axis of the sun following apparatus which is part of the frame 2 of the collector 1. The reflective panels are the only parts which need to be connected to the sun-following system which simplifies the structure for the rest of the system, particularly the receiver 4.

The receiver is preferably made of material with a high heat transfer coefficient, such as copper, steel, or aluminum.

The working fluid may consist of any suitable liquid or gas depending on the application of solar concentrating system. For example, if the application is a home hot water heating system, then the working fluid may be water. In cooler climates, the working fluid may be a substance which does not freeze at typical winter temperatures such as ethylene glycol. In such cases, a second heat exchanger, not exposed to the outside elements, is then used to heat the water. Such systems are in common use in Europe

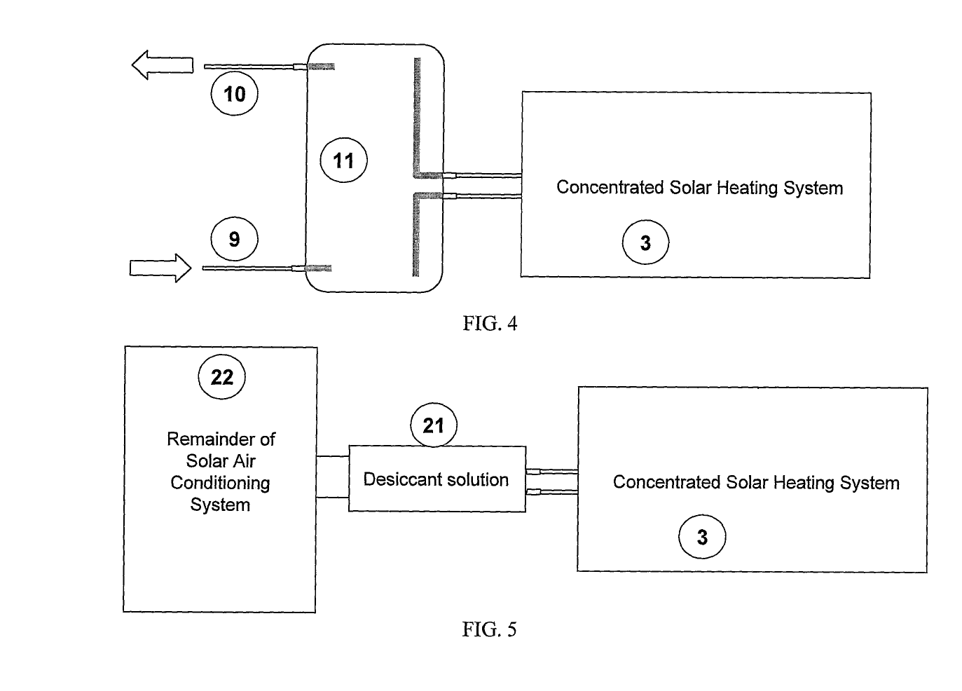

Reference is now made to FIG. 4 which shows a non-dimensionally scaled schematic diagram of a typical solar hot water system according to an embodiment of the present invention; Generally, cold water enters the inlet 9 at the bottom of the hot water storage tank 11. This water is then drawn into the solar collector 3. The solar collector heats water in the receiver which then is collected into a hot water storage tank 11. Hot water to be used is drawn from the outlet 10 top of the hot water tank. This figure simply shows the main idea and is not meant to be limiting. Some solar hot water systems use convection to circulate the water in the system. Some use water pumps. Some use heat exchangers. Any configuration currently in use for solar hot water heating may be used here.

Reference is now made to FIG. 5 which shows a non-dimensionally scaled schematic diagram of a possible desiccant-based solar air conditioning system according to an embodiment of the present invention. In this system, the working fluid is heated to a high temperature which is then used heat the desiccant 21 for purposes of drying the desiccant. The dried desiccant is then used in the remainder of the air conditioner 22 in the latent heat moisture absorption phase.

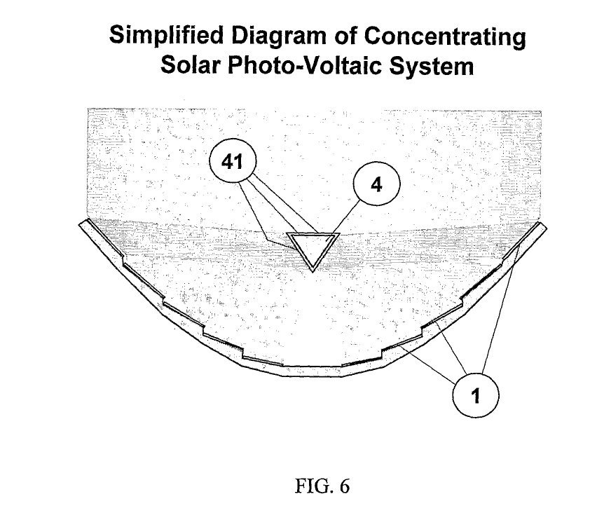

Reference is now made to FIG. 6 which is a cross sectional view of an embodiment of a solar collector 3 with photo-voltaic panels 41 affixed to the receiver. Energy reflected from the collector first impacts the photo-voltaic panels 41 which absorb a fraction of the energy according to their efficiency. Most of the remaining energy is collected by the receiver 4 to be used a heated working fluid for any of the application herein described.

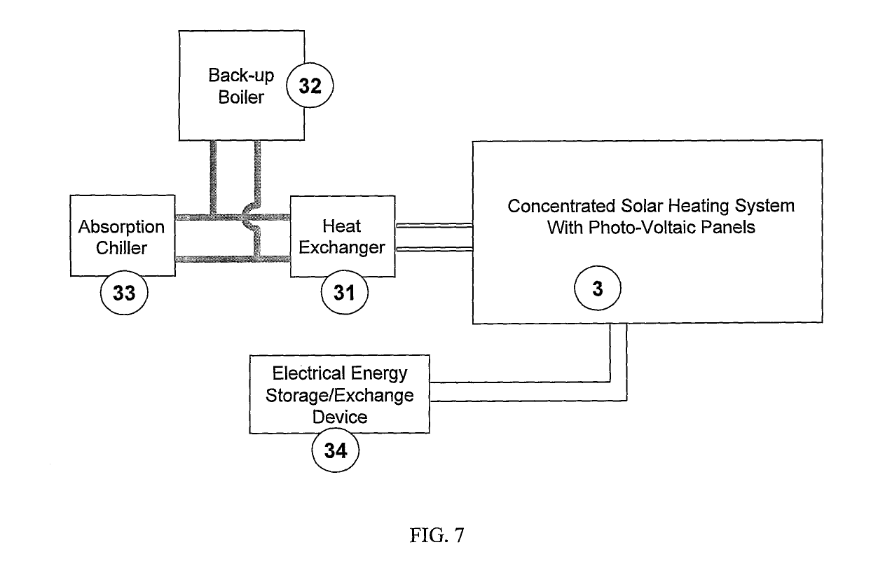

Reference is now made to FIG. 7 which shows a typical solar application involving an absorption chiller 33 according to an embodiment of the present invention; the solar collector 3 is used to heat the working fluid which gives its heat to the absorption chiller fluid in a heat exchanger 31. The absorption chiller 33 then provides hot and/or cold water or its working fluid, hot and/or cold air, for purposes of air conditioning refrigeration or whatever the chiller is designed for. For times when the solar collector 3 is unable to provide the necessary heated working fluid, a backup system 32 may be used. The figure also shows that the photo-voltaic panels could be used supplying electrical energy to a storage or exchange device 34.

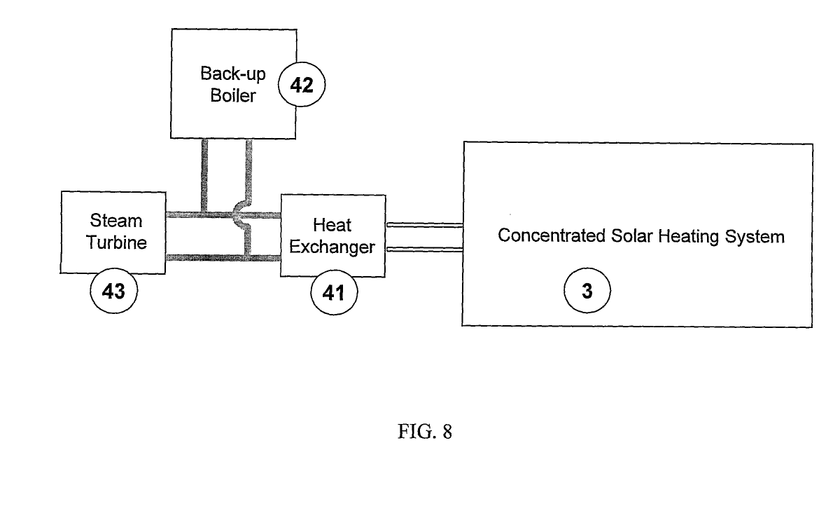

Reference is now made to FIG. 8 which shows a typical solar application involving a power generation device, in this case a steam turbine 43. Since the solar energy is concentrated it is very possible for the temperature to exceed the vaporization temperature of water to make steam. The steam could then be used to drive the steam turbine 43 for purposes of making electrical energy.

It will be appreciated that the described methods may be varied in many ways including, changing the order of steps, and/or performing a plurality of steps concurrently. It should also be appreciated that the above described description of methods and apparatus are to be interpreted as including apparatus for carrying out the methods, and methods of using the apparatus, and computer software for implementing the various automated control methods on a general purpose or specialized computer system, of any type as well known to a person or ordinary skill, and which need not be described in detail herein for enabling a person of ordinary skill to practice the invention, since such a person is well versed in industrial and control computers, their programming, and integration into an operating system.

It is noted that some of the above described embodiments may describe the best mode contemplated by the inventors and therefore may include structure, acts or details of structures and acts that may not be essential to the invention and which are described as examples. Structure and acts described herein are replaceable by equivalents performing the same function, even if the structure or acts are different, as known in the art. Therefore, the scope of the invention is limited only by the elements and limitations as used in the claims.

1. A system for collecting solar energy comprising:
a) A collector consisting of a number of flat reflective panels arranged in a parabolic arc so that solar energy is collected and concentrated;
b) A receiver centered at the focus of the parabola to receive the concentrated solar energy;
c) A working fluid within the receiver which absorbs the solar energy;
d) A sun-following mechanism such that the collected energy is always directed at the receiver during daylight hours;
e) A highly transmissive cover to the collector and dark internal coatings or colorings on all non-reflective surfaces to collect indirect solar radiation onto the receiver.

2. The system according to claim 1, whose working fluid is water in a direct solar water heater system.

3. The system according to claim 1, whose working fluid is used in a heat exchanger to transfer the collected energy to another device.

4. The system according to claim 3 wherein the other device is a solar air conditioner.

5. The system according to claim 3 wherein the other device is an absorption chiller.

6. The system according to claim 1, further comprising various means to prevent energy losses which includes any of the following:
a) A highly transmissive enclosure surrounding the receiver which may be partially or fully evacuated to minimize convection loss;
b) A highly transmissive enclosure across the opening of the parabolic housing in order to reduce convection losses and to collect indirect solar radiation from the environment;
c) Adding dark color to all nonreflecting surfaces in the collector-receiver assembly to improve the absorption of solar radiation;
d) Adding antireflective coatings to any transmissive surface to improve transmissivity;
e) Adding reflection-enhancing films or coatings to the mirror surfaces to improve reflectivity; and
f) Adding absorption-enhancing films or coatings to the receiver surfaces to improve absorption of solar energy.

7. The system according to claim 1, wherein the receiver consists of at least one coil of tubing with the second and further coils being concentric with the first coil.

8. The system according to claim 1, wherein the receiver consists of a series of tubes arranged in such a way so that the working fluid has flow passages in both directions to enhance the heat transfer to the working fluid.

9. The system according to claim 1, wherein the reflective panels are of different sizes to maintain the same exposure area on the receiver.

10. The system according to claim 1, wherein the reflective panels are all the same size to simplify the manufacture of the collector.

11. The system according to claim 1, wherein the sun-following mechanism is any known single or dual axis driving system.

12. The system according to claim 1, wherein the flat reflective panels are replaced by a parabolic arc reflector.

13. The system according to claim 1, further comprising photo-voltaic panels located on the receiver to generate electricity from the collected and concentrated solar energy.

14. The system according to claim 13, further comprising making use of the receiver to remove excess heat or unused solar energy from the photovoltaic panels to maintain the panels at a significantly lower temperature thereby maintaining higher efficiency.

15. The system according to claim 14, further comprising using the heated working fluid in other devices such as a heat exchanger for a hot water system, as a heat source for drying desiccants in a solar air conditioner, as a heat source for an absorption chiller, or any other device for which a heated fluid may a useful source of energy.

16. The system according to comprising more than one of the systems in claim 1 wherein a plurality of systems are linked together either in parallel or in series.

17. The system according to claim 3 wherein the other device is an adsorption chiller.

18. The system according to claim 13, wherein the receiver provided with photo-voltaic panels is configured in triangular prism.

19. The system according to claim 13, wherein the prism is equilateral.

20. The system according to comprising more than one of the systems in claim 13 wherein a plurality of systems are linked together either in parallel or in series.
